(19) United States
(12) Patent Application Publication
(10) Pub. No.: US 2025/0142757 A1
(43) Pub. Date: May 1, 2025

(54) SECURITY BEZELS WITH INTERCHANGEABLE LOCKING MECHANISMS

(71) Applicant: Dell Products L.P., Round Rock, TX (US)

(72) Inventors: SEAN P. O’DONNELL, Poughkeepsie, NY (US); LIBERTAD PALOMA ESCOBAR CARRIZALES, Austin, TX (US); PETER KALTENBACH, Austin, TX (US)

(21) Appl. No.: 18/496,232

(22) Filed: Oct. 27, 2023

(51) Int. Cl. H05K 7/14

(52) U.S. Cl. CPC H05K 7/1402; H05K 7/1495

(57) ABSTRACT

Methods, systems, and devices for providing computer implemented services are disclosed. To provide the computer implemented services, a data processing system may include various hardware components. To secure the various hardware components, the data processing system may include a security bezel. The security bezel may be for a chassis of the data processing system, the hardware components being positioned on an interior of the chassis. The security bezel may have a structural body for securing access to an interior of the chassis, the structural body forming a partial covering for a two-dimensional surface. The security bezel may further have a locking latch adapted to reversibly secure the structural body to the chassis, and the locking latch may include a lock space to receive an interchangeable locking mechanism.

### FIELD

Embodiments disclosed herein relate generally to device management. More particularly, embodiments disclosed herein relate to managing security of devices.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIGS. 1A-1B show block diagrams illustrating a system in accordance with an embodiment.

FIG. 2A-2E show diagrams illustrating a security bezel in accordance with an embodiment.

FIG. 3 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for providing, at least in part, computer implemented services. To provide the services, a system may include any number of hardware components (e.g., storage devices, memory modules, processors, etc.). To facilitate placement and management of the hardware components, the hardware components may be positioned in a chassis. For example, the chassis may be a form factor compliant (e.g., a ½U sled) enclosure. The enclosure, to provide its functionality, may include an opening through which access to the hardware components is provided. For example, this access may facilitate insertion and/or removal of hot swap components and may facilitate airflow into and/or out of the enclosure.

Consequently, access to the hardware components provided by the opening may leave the hardware components vulnerable to compromise (e.g., due to theft and/or damage of the hardware components). If damaged, the hardware components may be prevented from providing various functionalities (on which the computer implemented services depend) as intended. Additionally, for example, the hardware components may be stolen using the access. Once removed, the stolen hardware components would not be capable of providing the various functionalities on which the computer implemented services depend. Thus, the vulnerability provided by the access may increase a likelihood of compromise of the computer implemented services.

To decrease the likelihood of compromise of the hardware components (and thus, the computer implemented services), the data processing system may include a security bezel to manage the access to the hardware components.

To manage the access, the security bezel may include a structural body that prevents intrusion into an interior of the chassis. To prevent the intrusion, the structural body may be implemented with a structure adapted to resist deformation from force applied to the security bezel while allowing a traversal of gasses through the chassis. This structure may be oriented and positioned on a two-dimensional (2D) surface that spans the opening of the chassis.

Additionally, the security bezel may be secured to the chassis thereby allowing the security bezel to stay at a fixed position (relative to the chassis) that substantially covers the opening. For example, the structure may be integrated with a locking mechanism, the locking mechanism allowing the security bezel to be secured to a position unless actuated by a lock. By doing so, the security bezel may adequately cover the opening while facilitating management for the access.

However, some users of the security bezel may require various (e.g., different) levels of security to manage the access. For example, some users may require high levels of security (e.g., the locking mechanism may include motors, sensors, and/or other features). In contrast, other users may only require simple (e.g., low) levels of security (e.g., the locking mechanism may include a key driven lock cylinder).

To secure the security bezel to the chassis while allowing for customizable levels of security, the security bezel may include a locking latch that allows for integration with an interchangeable locking mechanism. For example, the locking latch may include a mating member to facilitate the physical connection to the chassis, and a lock space adapted to integrate with an interchangeable locking mechanism.

Thus, by including the locking latch, the security bezel may be properly secured to the chassis and adequately cover the opening to prevent the intrusion, thereby limiting access to the hardware components within the interior of the enclosure and decreasing a likelihood of compromise of the hardware components on which the computer implemented services depend.

In an embodiment, a security bezel for a chassis of a data processing system is provided.

The security bezel may include a structural body for securing access to an interior of the chassis, the structural body forming a partial covering for a two-dimensional surface, the structural body adapted to facilitate traversal of gases through the two-dimensional surface, and resist deformation due to force applied to the security bezel to maintain the partial covering for the two-dimensional surface, and a locking latch adapted to reversibly secure the structural body to the chassis; and a lock space to receive an interchangeable locking mechanism.

The locking latch may include a retractable mating member that may include receptacles for making a first connection between the interchangeable locking mechanism and the retractable mating member to allow the interchangeable locking mechanism to move the retractable mating member between two positions, and extended portions for making a second connection between the chassis and the retractable mating member while the retractable mating member is in a first position of the two positions, the structural body being secured to the chassis while the second connection is in place.

The security bezel may be reversible, and the lock space may accommodate insertion of the interchangeable locking mechanism from both sides of the security bezel.

The extended portions may have an asymmetric shape, the asymmetric shape fixedly securing the structural body to the chassis while the security bezel is in a first orientation, and not securing the structural body to the chassis while the security body is in a second orientation, where reversing the security bezel from the first orientation may place the security bezel in the second orientation.

The locking latch may include a return spring adapted to return the extended portions to the first position from a second position of the two positions while the interchangeable locking mechanism is not applying any force to the retractable mating member.

The retractable mating member may further include a member body, and

a first guiding arm extending from the member body, the first guiding arm may include a receptacle of the receptacles, and wherein the extended portions extend from the member body.

The first guiding arm may restrict a motion path of the extended portions while the extended portions move between the first position and the second position.

The first guiding arm and the extended portions may be on different sides of the member body.

The retractable mating member may further include a second guiding arm, the second guiding arm being on an opposite side of the lock space from the first guiding arm.

The security bezel may further include the interchangeable locking mechanism, the interchangeable locking mechanism adapted to be inserted into the lock space and mechanically coupled to portions of the locking latch while inserted in the lock space.

While mechanically coupled to the portions of the locking latch, actuation of the interchangeable locking mechanism reversibly secures the security bezel to the chassis.

In an embodiment, a data processing system is provided that may include the security bezel as discussed above.

In an embodiment, an enclosure that may include the security bezel as discussed above is provided.

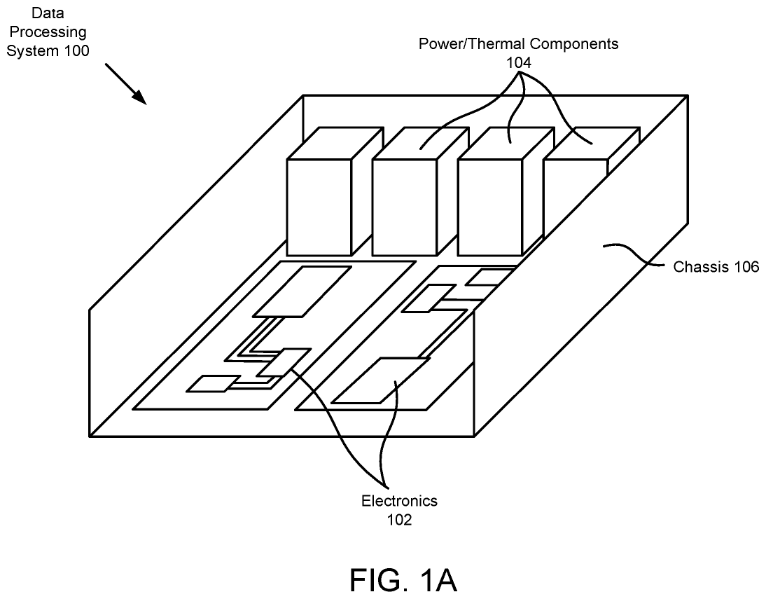

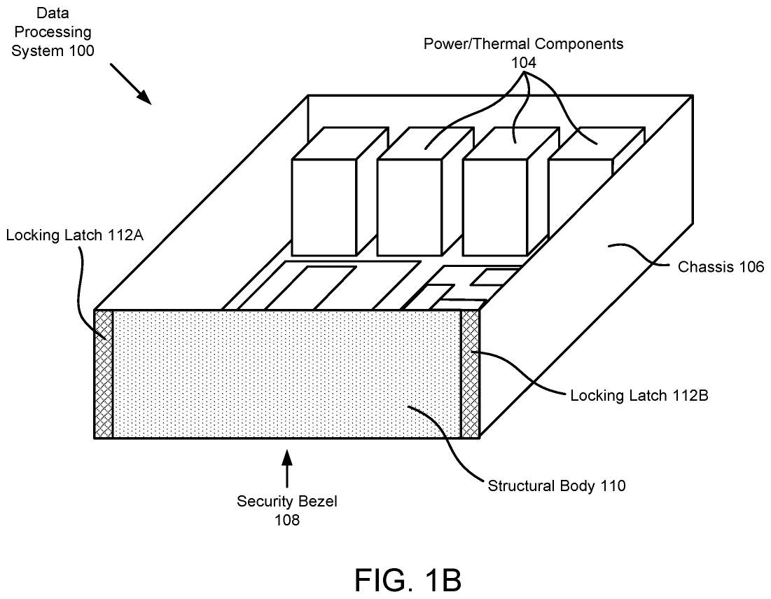

Turning to FIG. 1A, a diagram illustrating a data processing system in accordance with an embodiment is shown. The data processing system shown in FIG. 1A may provide computer implemented services. The computer implemented services may include any type and/or quantity of computer implemented services. For example, the computer implemented services may include data storage services, instant messaging services, database services, and/or any other type of service that may be implemented with a computing device.

To provide the computer implemented services, the data processing system may include various hardware components. These hardware components may facilitate various functionalities of a data processing system (e.g., 100). For example, to provide the computer implemented services, data processing system 100 may include electronics 102, power/thermal components 104, and chassis 106. Each of these is discussed below.

Electronics 102 may include various types of hardware components such as processors, memory modules, storage devices, communications devices, and/or other types of devices. Any of these hardware components may be operably connected to one another using circuit card traces, cabling, connectors, etc. that establish electrical connections used to transmit information between the hardware components.

Power/thermal components 104 may power any of the components of data processing system 100 and/or thermally manage any of the components of data processing system 100. For example, power/thermal components 104 may include power supplies, fans, and/or other types of devices usable to power and/or thermally manage the components.

Any of the components of data processing system 100 may be positioned in chassis 106. Chassis 106 may include an enclosure in which physical structures of electronics 102 (e.g., processors, memory, etc.) and power/thermal components 104 (e.g., power supplies, fans, etc.) may be positioned. Chassis 106 may facilitate placement and management of electronics 102 and/or other components in a computing environment.

To provide its functionality, chassis 106 may be implemented with a form factor compliant (e.g., a ½U sled) enclosure usable to integrate data processing system 100 into a high-density computing environment, such as a rack mount chassis management system.

To facilitate the placement and management of the components within chassis 106, chassis 106 may include an opening (e.g., on a front side and/or a back side of chassis 106) through which access to the hardware components of data processing system 100 is provided. For example, this access may facilitate insertion and/or removal of hot swap components for chassis 106. Additionally, the opening may facilitate airflow into and/or out of chassis 106, thereby providing additional thermal management (e.g., cooling) for data processing system 100.

However, the access to the hardware components provided by the opening in the enclosure may leave data processing system 100 vulnerable to compromise (e.g., due to theft and/or damage of the hardware components). For example, a negligent and/or an incompetent individual may interact with the hardware components using the access, resulting in bent contact pins, ruptured liquid cooling tubes, and/or other physical damages caused by the individual. If damaged, the hardware components may be prevented from providing various functionalities (on which the computer implemented services depend) as intended.

Additionally, for example, the hardware components may be stolen from chassis 106 using the access. Once removed, the stolen hardware components may not be available to data processing system 100, and therefore, would not be capable of providing the various functionalities on which the computer implemented services depend.

Thus, the vulnerability provided by the access may increase a likelihood of compromise of the computer implemented services.

In general, embodiments disclosed herein relate to systems, methods, and devices for managing security of a data processing system. More particularly, embodiments disclosed herein may relate to security management of hardware components of a data processing system. The security of the hardware components may be managed to decrease a likelihood of compromise caused by access to the hardware components. To do so, the data processing system (e.g., 100) may include a security bezel as seen in FIG. 1B (discussed below).

While illustrated in FIG. 1A with a limited number of specific components, a data processing system may include additional, fewer, and/or different components without departing from embodiments disclosed herein.

Turning to FIG. 1B, a diagram illustrating data processing system 100 in accordance with an embodiment is shown. As previously discussed, data processing system 100 may provide computer implemented services. To do so, data processing system 100 may include various hardware components that provide various functionalities on which the computer implemented services depend. However, access to the hardware components, provided by an opening in chassis 106, may leave data processing system 100 vulnerable to compromise, thereby increasing a likelihood of compromise to the computer implemented services. To decrease the likelihood of compromise caused by the access, data processing system 100 may include security bezel 108, as shown in FIG. 1B.

Security bezel 108 may prevent access to the hardware components positioned within an interior of chassis 106. To do so, security bezel 108 may (i) be implemented, at least in part, with a structural body (e.g., 110), and (ii) be positioned on a two-dimensional (2D) surface that spans a distance across the opening of chassis 106, discussed previously. Thus, security bezel 108 may prevent intrusion into the interior by obstructing passage through the 2D surface, discussed further below.

Additionally, security bezel 108 may be reversible. For example, security bezel 108 may be positioned across the opening of chassis 106 (on the 2D surface), as mentioned above. While positioned across the opening, as shown in FIG. 1B (e.g., in a first orientation), security bezel 108 may have a first surface area that faces an exterior of chassis 106 (“a front side”) and may have a second surface area that faces an interior of chassis 106 (“a back side”). When reversed, security bezel 108 may be removed from the opening, flipped, and repositioned across the opening (e.g., in a second orientation), resulting in the front side facing the interior and the back side facing the exterior. By being reversible, security bezel 108 may change between the first and/or the second orientation.

Although described using a first and/or a second orientation, it will be appreciated that security bezel 108 may change between any number of orientations without departing from embodiments disclosed herein.

These orientations (e.g., the first and/or the second orientations) may each provide any number of functionalities, and the functionalities may include any number of same and/or different functionalities when compared between the orientations. For example, while in the first orientation, security bezel 108 may be lockable, thereby allowing security bezel 108 to be secured to a position unless actuated by a lock. While in the second orientation, security bezel 108 may be held in place but not locked so that security bezel 108 can be placed in the position temporarily and may be removed without actuating the lock.

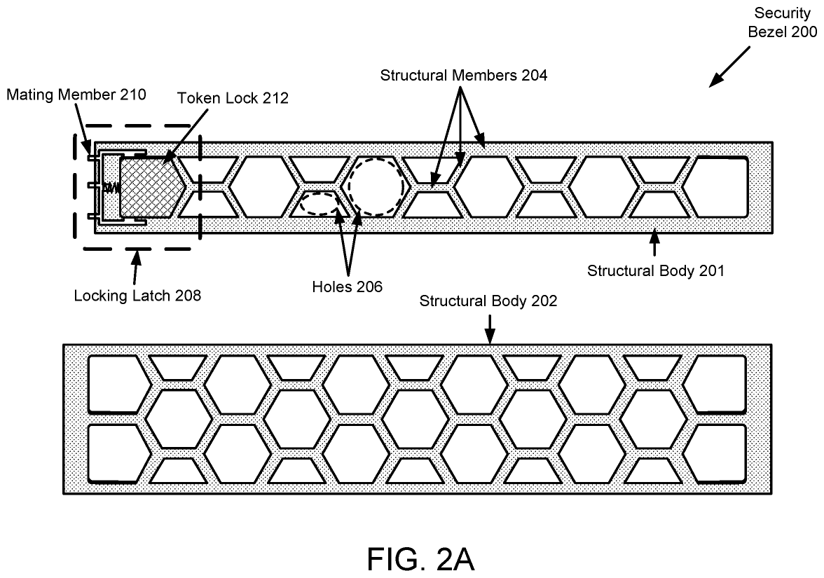

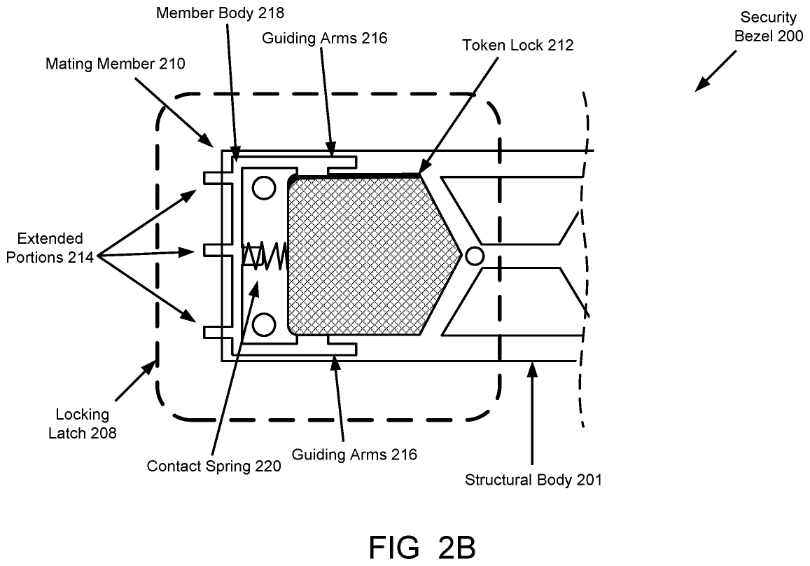

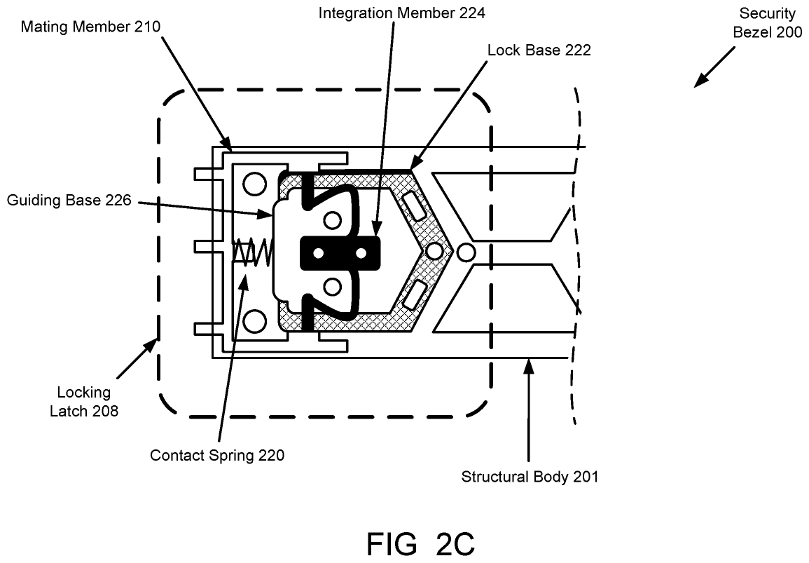

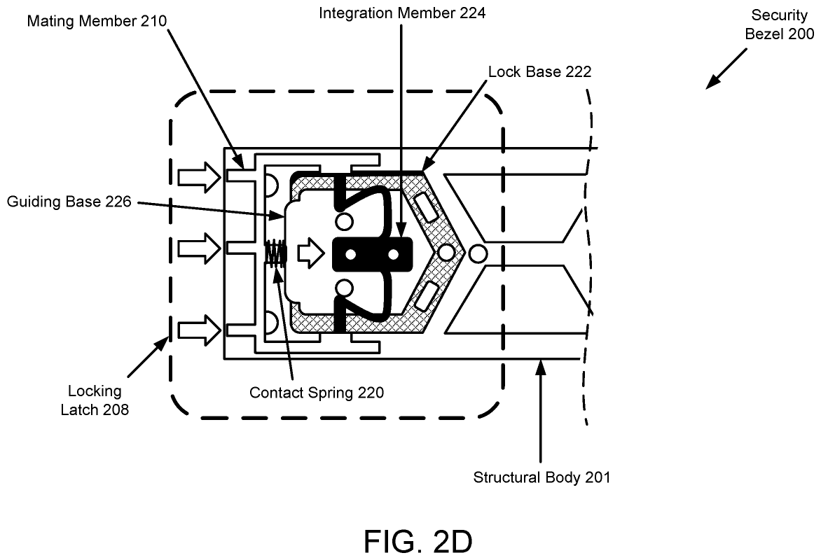

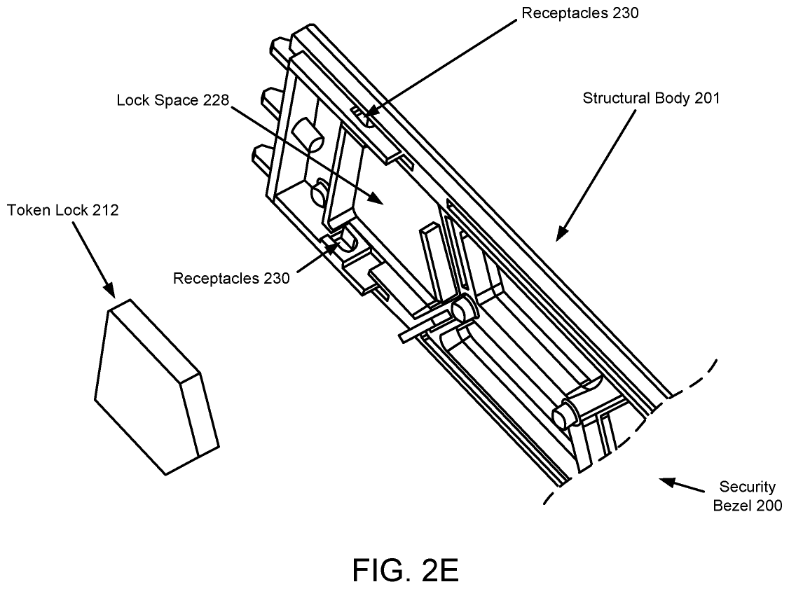

As noted above, security bezel 108 may obstruct the passage through the 2D surface. To obstruct the passage, structural body 110 may be adapted to (e.g., may have a structure, may be formed from certain materials, etc.) resist deformation from force applied to security bezel 108. Therefore, when positioned on the 2D surface, structural body 110 may pose as an obstruction blocking entry into the interior through the surface. For additional information regarding the structural body, refer to FIG. 2A.

Additionally, to provide its functionality, security bezel 108 may cover substantially all of the opening in chassis 106. To maintain the substantial coverage of the opening, security bezel 108 may be securely attached to chassis 106. To do so, security bezel 108 may include locking latch 112A, locking latch 112A being positioned with a corresponding side of structural body 110.

Locking latch 112A may be adapted to reversibly secure structural body 110 (and therefore, security bezel 108) to chassis 106. Additionally, locking latch 112A may provide its functionality based on an orientation of security bezel 108 (e.g., when changing between the orientations, a degree of security provided by the interchangeable locking mechanism may also change). For example, while in the first orientation, locking latch 112A may provide a lock to manage the access. This lock may require locking and/or unlocking when the access, for example, is being prevented or facilitated, respectively.

Additionally, while in the second orientation, locking latch 112A may be integrated with the lock just as when in the first orientation. However, due to the second orientation, actuating the lock may be unable to influence the management of the access (e.g., this may be due to a shape of a mating member, discussed further below, and how that shape may interact with a shape of a complementary mating member, also discussed further below.)

To provide its functionality, locking latch 112A may include (i) a mating member, mentioned above and adapted to physically connect security bezel 108 to chassis 106, and (ii) a lock space adapted to integrate with the interchangeable locking mechanism. Each of these is discussed below.

To physically connect security bezel 108 to chassis 106, the mating member may be manipulated to facilitate physical coupling (e.g., an attachment) with a complementary mating member of chassis 106. For example, the mating member may be aligned with the complementary mating member of chassis 106 (e.g., by being positioned on the 2D surface). Security bezel 108 may then be pushed against a side of the opening (e.g., a side of chassis 106) to cause (e.g., manipulate) an interaction between the mating member and the complementary mating member. This interaction may thereby result in the physical coupling between structural body 110 and chassis 106.

To facilitate this physical coupling, the mating member may be positioned, relative to structural body 110, to extend away from structural body 110 from at least one side (e.g., a corresponding side) of structural body 110.

To secure security bezel 108 to a fixed position (e.g., after the mating member is physically coupled), a lock may be integrated with locking latch 112A. This lock may be actuated using, for example, a key to limit and/or facilitate further manipulation of the mating member. For example, when secured using the lock, the mating member may be fixed (at least temporarily) to a first position unless interacted with in a particular manner (e.g., with the key). Additionally, for example, the key may be used to actuate the lock and thereby allow the position of the mating member to change (with respect to locking latch 112A) from the first position to a second position.

However, some users of security bezel 108 may require various (e.g., different) levels of security to manage the access. For example, some users may require high levels of security (e.g., the lock may include motors, sensors, and/or other features). In contrast, other users may only require simple (e.g., low) levels of security (e.g., the lock may include a key driven lock cylinder).

To secure security bezel 108 to chassis 106 while allowing for customizable levels of security, locking latch 112A may include the lock space that allows for integration with an interchangeable locking mechanism. This interchangeable locking mechanism may be, for example, chosen by a user of security bezel 108 based on requirements regarding a level of security corresponding with the user's needs.

It will be appreciated however, that locking latch 112A may or may not include the interchangeable locking mechanism. Thus, a user of the security bezel may choose a different interchangeable locking mechanism based on the user's needs. By including the lock space, the user may also be able to integrate the interchangeable locking mechanism with security bezel 108.

Additionally, the lock space may accommodate insertion of the interchangeable locking mechanism from both sides of security bezel 108 (e.g., the interchangeable locking mechanism may be integrated from the exterior of chassis 106 regardless of the orientation of security bezel 108).

Thus, the particular lock used to secure security bezel 108 to chassis 106 may be customized based on, for example, a user of chassis 106. For example, users of chassis 106 that desire high but costly security may elect to use a lock that includes motors, sensors, and/or other features. In contrast, other users of chassis 106 that desire low cost but dependable security may elect to use a lock that includes a key driven lock cylinder.

By managing manipulation of the mating member using an interchangeable locking mechanism that is integrable with the lock space, security bezel 108 may manage the access through the 2D surface. Thus, by managing the access through the 2D surface, a likelihood of compromise of the hardware components may be decreased.

Additionally, for example, changing the orientation of security bezel 108 may change an influence over the degree of the security that the interchangeable locking mechanism has on the mating members. For example, if security bezel 108 is in the first orientation and the interchangeable locking mechanism is interacted with in the particular manner, the interchangeable locking mechanism may manipulate the mating members from being coupled to decoupled from one another (and/or vice versa). However, if security bezel 108 is in the second orientation and the interchangeable locking mechanism is interacted with in the particular way, the interchangeable locking mechanism may be unable to manipulate the mating members from being coupled to decoupled (and/or vice versa).

For example, and as previously discussed, while in the first orientation, security bezel 108 may be lockable. Security bezel 108 may thereby be secured to a position unless actuated by a lock. By being lockable, authorization required for access to the hardware components may be managed. For example, a technician may have the required authorization, and therefore may have a key for the lock. Thus, the technician may use the key to actuate the lock and gain access to the hardware components.

While in the second orientation, security bezel 108 may be held in place but not locked so that security bezel 108 can be placed in the position temporarily. Thus, security bezel 108 may be removed without actuating the lock. For example, assume the technician is servicing multiple chassis. The technician may place security bezel 108 over the opening but in the second orientation. Therefore, the technician may not need to unlock security bezel 108 every time the technician switches between working on chassis 106 and working on other chassis (which may be tedious and time consuming).

This difference in the influence may be due to, for example, a shape of the mating members with regard to the corresponding mating members. For additional information regarding the shape of the mating members, refer to FIG. 2B.

By using locking latch 112A to physically couple a corresponding side of structural body 110 to a complementary side of chassis 106, security bezel 108 may be positioned on the 2D surface to substantially cover the opening, at least temporarily.

By securing the physical coupling using an interchangeable locking mechanism, security bezel 108 may be fixed to the position on the 2D surface unless the interchangeable locking mechanism is interacted with in a particular way. (and/or is in an orientation that prevents it from doing so). Thus, the substantial covering may be maintained over the opening in chassis 106 by security bezel 108.

It will be appreciated that although described as including a single locking latch (e.g., 112A), a security bezel (e.g., 108) may include more than one locking latch (e.g., 112A and/or 112B) that are simultaneously positioned with corresponding sides of the structural body. For example, security bezel 108 may include (i) structural body 110, (ii) locking latch 112A, and/or (iii) locking latch 112B, as illustrated in FIG. 1B.

For additional information regarding the locking latches and/or the security bezel, refer to FIG. 2A.

While illustrated in FIG. 1B with a limited number of specific components, a system may include additional, fewer, and/or different components without departing from embodiments disclosed herein.

As noted above, a security bezel may be used to secure hardware components in a chassis. To do so, the security bezel may include a structural body and at least one locking latch. FIG. 2A shows a diagram illustrating examples of a security bezel in accordance with an embodiment.

Turning to FIG. 2A, a first diagram illustrating a security bezel (e.g., 200) in accordance with an embodiment is shown. It will be appreciated that security bezel 200 may be similar to the security bezel discussed with respect to FIG. 1B (e.g., 108) and may include (i) a structural body (e.g., 201 and/or 202) and (ii) a locking latch (e.g., 208). In FIG. 2A, the viewpoint may be from a front of security bezel 200 (e.g., the front being how the security bezel would be viewed from outside of a chassis) rather than from a perspective view of a security bezel as shown in FIG. 1B.

As discussed above, security bezels (e.g., 108 and/or 200) may facilitate security management for various hardware components of data processing systems (e.g., 100) by preventing access to the hardware components. To prevent access to the hardware components, the security bezels may be implemented using rigid, self-supporting super structures (e.g., structural bodies 201-202). These super structures may each be adapted to cover an opening of a respective chassis (e.g., chassis 106, previously discussed) that provides access to the hardware components. By having one of structural bodies 201-202 cover an access (e.g., an opening), the structural body may screen the access to an interior of the respective chassis while enabling airflow into and/or out the respective chassis.

It will be appreciated that structural bodies 201-202 are illustrated as having different sizes (e.g., dimensions) due to being examples of structural bodies for security bezels of various sizes for enclosures commonly used, for example, for rack mount chassis management systems. For example, structural body 201 may be usable in conjunction with a 1-rack unit (1U) size chassis, and structural body 202 may be usable in conjunction with a 2-rack unit (2U) size chassis.

To provide their functionalities, structural bodies 201-202 may include structural members (e.g., 204) and holes (e.g., 206). For example, each of these is discussed below with regard to structural body 201.

The structural members (e.g., 204) may be arranged to partially cover a surface (e.g., the two-dimensional (2D) surface that spans a distance across the opening of chassis 106) and form a self-supporting structure (e.g., structural body 201).

Each structural member of the structural members may (i) span a distance between two points on the 2D surface, and (ii) resist deformation due to force applied to any number of the structural members.

These structural members may bound the holes (e.g., 206) through which gases may traverse. More particularly, each hole of the holes may be at least partially bound by a portion of the structural members. These boundaries (facilitated by the structural members) may result in an arrangement of at least a portion of the holes into an at least partial honeycomb pattern.

It will be appreciated that although illustrated as having a partial honeycomb pattern (referred to as a “first pattern”) in FIG. 2A, a structural body (e.g., 201) may be fabricated to have a complete honeycomb pattern (e.g., a pattern that includes more than one partial honeycomb pattern). For example, structural body 202 may be fabricated to include the first pattern and a second pattern that is similar to the first pattern. The first pattern and the second pattern may be physically connected to one another, and the second pattern may be positioned above or below the first pattern (from the viewpoint of FIG. 2A). By fabricating the security bezel to include any number of partial honeycomb patterns positioned above or below the first pattern, the security bezel may be fabricated to have a complete honeycomb pattern.

While described with respect to a honeycomb pattern, it will be appreciated that the holes may take on other patterns without departing from embodiments disclosed herein.

To further screen access to the hardware components (e.g., manage the access), the holes may have shapes and sizes that prevent general physical access to the interior of the respective chassis. Thus, entities and/or forces may be inhibited from interacting with the hardware components from an exterior of the respective chassis. However, the holes may facilitate movement of some objects (e.g., specialized tools) below a size threshold through the surface while preventing components within the respective chassis from being removed through the holes.

For example, these holes may facilitate the insertion of a key into a lock (e.g., an interchangeable lock mechanism, previously mentioned with regard to FIG. 1B) residing in a lock space. By inserting the key into the lock to manipulate the lock, the lock may further manipulate a latch mechanism (e.g., the mating members, previously discussed). Thus, interaction with the lock may manipulate the latch mechanism in a particular manner (e.g., the particular manner, previously discussed and assuming a correct key (a key providing authority for the access) is used) to manage access to the hardware components.

Although described with respect to an interchangeable lock mechanism (e.g., a lock), it will be appreciated that a security bezel may include a latch mechanism and a lock space, but may not include a lock (e.g., on which manipulation of the latch mechanism depends). For example, the lock space may be adapted to receive a type of the interchangeable locking mechanism, the type being determined by, for example, an intended user of the data processing system of which the respective chassis is a part. Because the intended user may decide on the type of the interchangeable locking mechanism, security bezel 108 may only include the mating members and the lock space to allow for customization by the intended user.

For additional information regarding the interchangeable locking mechanism, refer to FIGS. 2C-2D.

As noted above, a latch mechanism may be manipulated in a particular manner to manage access to the hardware components. This latch mechanism may be implemented, at least in part, by at least one mating member (e.g., 210). For example, mating member 210 may be included in locking latch 208 of security bezel 200 and may be adapted to reversibly secure structural body 201 of security bezel 200 to chassis 106.

However, as previously discussed with regard to FIG. 1B, structural body 201 may need to cover substantially all of the opening in chassis 106. Consequently, if security bezel 200 is removed from the opening (e.g., by not being adequately secured to chassis 106) and/or is otherwise unable to span the entirety of the opening, security bezel 200 may be unable to adequately cover the opening to prevent the intrusion.

For example, an individual proximate to the data processing system may manually remove security bezel 200 from the opening by manipulating mating member 210. In an embodiment, this individual may be providing maintenance for the data processing system and may have required permissions to perform the maintenance (e.g., may be authorized to provide maintenance). In another embodiment, this individual may not have required permissions to access the interior of the chassis and may thereby increase the likelihood of compromise to the hardware components.

To manage the latch mechanism, locking latch 208 (and therefore, security bezel 200) may include a lock space in which token lock 212 may be integrated. Token lock 212 may be implemented using an interchangeable locking mechanism as previously discussed. For additional information regarding locking latch 208, refer to FIGS. 2B-2E.

By including the lock space to integrate the interchangeable locking mechanism (and thereby providing a means of managing the latch mechanism), security bezel 200 may prevent intrusion into the interior of chassis 106 by obstructing passage through the 2D surface (e.g., unless permission for access is provided, such as a key for a lock). Thus, by including a locking latch such as locking latch 208, a likelihood of compromise to the hardware components may be decreased.

While illustrated in FIG. 2A with a limited number of specific components, a security bezel may include additional, fewer, and/or different components without departing from embodiments disclosed herein.

As noted above, a security bezel may be used to manage access to an interior of a chassis, the security bezel including a structural body and a locking latch. This locking latch may include a latch mechanism and a lock space. This latch mechanism may be (i) implemented (at least in part) by at least one mating member (e.g., 210) to facilitate the access to the interior, and (ii) managed by an interchangeable locking mechanism integrated into the lock space. FIGS. 2B-2E show diagrams illustrating an example of a security bezel in accordance with an embodiment.

Turning to FIG. 2B, a second diagram illustrating a security bezel (e.g., 200) in accordance with an embodiment is shown. In FIG. 2B, the viewpoint may be a magnification of locking latch 208, as shown in FIG. 2A.

As previously discussed, an opening in a chassis (e.g., 106) may provide access to an interior of the chassis, the chassis housing various hardware components on which computer implemented services depend. To limit (e.g., by managing) access to the hardware components through the opening, thereby decreasing a likelihood of compromise of the hardware components, a security bezel (e.g., 200) may be secured to a position to cover the opening. For example, to cover the opening, security bezel 200 may include structural body 201 (previously discussed). To secure structural body 201 to the position, security bezel 200 may include locking latch 208, discussed below.

Locking latch 208 may connect to a side portion of structural body 201 to manage a first connection between the side portion and a side of the chassis (and therefore, a side of the opening). For example, locking latch 208 may connect to the side portion by being encased (at least partially) within an interior of the side portion of structural body 201 (e.g., as depicted in FIG. 2B). When managing access to the hardware components, portions of locking latch 208 may change between being positioned within the interior of the side portion to an exterior of the side portion (discussed further with regard to FIGS. 2C-2D).

To do so, locking latch 208 may include (i) a latch mechanism such as mating member 210 for facilitating the first connection, and (ii) a lock space for integrating an interchangeable locking mechanism such as token 212 (e.g., to change the positioning of the portions of locking latch 208, discussed further below).

Mating member 210, as noted above, may be a latch mechanism that when manipulated in a particular manner may be used to facilitate the first connection between security bezel 200 and chassis 106. Mating member 210 may thereby contribute to a management of the access to the hardware components.

To facilitate the first connection, mating member 210 may be adapted to (i) physically couple with corresponding mating members of the chassis, (ii) physically decouple from corresponding mating members of the chassis, and (iii) be manipulated, for example, by an interchangeable locking mechanism, discussed further below.

To provide its functionality, mating member 210 may include at least one extended portion (e.g., extended portions 214), at least one guiding arm (e.g., guiding arms 216), and a member body (e.g., member body 218). Each of these is discussed below.

To connect structural body 201 to the chassis, mating member 210 may include, for example, extended portions 214. Extended portions 214 may (i) be implemented with protrusions on mating member 210 that extend away from member body 218, and (ii) have a shape adapted to facilitate the first connection, thereby securing security bezel 200 to the chassis.

For example, each of extended portions 214 may be implemented with an appendage shaped like a hook. This hook may correspond with structures on the chassis. For example, one of these structures may be a recess in the chassis wall (e.g., on a side of the opening). To make the first connection, at least in part, the hook may be manipulated in a first manner to interact with the structure (e.g., the hook may be moved at least partially through the recess. Based on this first manner, the hook may maintain a particular position until manipulated in a second manner (e.g., physically unhooked by an individual and/or otherwise using another latch mechanism).

This second manner may include, for example, extended portions 214 being placed in a second position from the particular position by retracting extended portions 214 into structural body 201. To do so, locking latch 208 may include, for example, the at least one guiding arm (e.g., guiding arms 216), discussed below.

To connect structural body 201 to mating member 210, mating member 210 may include, for example, guiding arms 216. Guiding arms 216 may be implemented with receptacles (e.g., similar to the recesses through which the hook shapes described with respect to extended portions 214 were at least partially moved through). These receptacles may be adapted to interact with portions of token lock 212, thereby allowing for manipulation of the receptacles by token lock 212.

For example, the receptacles may be shaped like hooks and these hooks may point inward with respect to the lock space in which token lock 212 is positioned. When token lock 212 is integrated into security bezel 200, recesses in token lock 212 may allow for an interaction between the receptacles. This interaction may include, for example, securing the receptacles to a position in and/or around token lock 212. For additional information regarding the receptacles, refer to FIG. 2E.

Once the receptacles are secured to token lock 212, the receptacles may be moved between two positions based on manipulation by token lock 212. This manipulation may further affect extended portions 214 as discussed above. To do so, mating member 210 may further include member body 218.

Member body 218 may be implemented using a rigid structure adapted to impart (i) physical strength to mating member 210, (ii) stability to the first connection and second connection facilitated by extended portions 214 and guiding arms 216, respectively, and (iii) facilitate positioning of mating member 210.

To do so, member body 218 may connect extended portions 214 to guiding arms 216. Additionally, member body 218 may have a shape and size adapted to (i) limit a distance at which mating member 210 (and therefore extended portions 214) may, for example, protrude out of the side portion, and (ii) facilitate a linear traversal between two positions by having, for example, a same height as the structural body 201 (e.g., thereby keeping mating member 210 from freely moving about the interior of the side portion of structural body 201).

For example, while mating member 210 is in the first position, extended portions 214 may extend from perforations in the side portion of structural body 201, the extension being limited by member body 218 being physically withheld due to resistance from portions of structural body 201 between the perforations.

To be kept in this first position, locking latch 208 may include token 212. For additional information regarding token 212, refer to FIGS. 2C-2E.

Additionally, to be kept in this first position, locking latch 208 may include, for example, contact spring 220. In an embodiment, contact spring 220 may provide a constant force that pushes member body 218 away from, for example, token lock 212. However, in another embodiment, contact spring may provide a constant force that pulls member body 218 toward token lock 212, discussed below.

To reposition mating member 210 to the second position, token lock 212 may be interacted with (e.g., an individual may input a passcode, use a key, etc.) to instigate a repositioning of guiding arms 216 to the second position. In doing so, the movement of guiding arms 216 may cause the movement of member body 218 (and therefore, extended portions 214), thereby decreasing a distance between member body 218 and token lock 212. Thus, extended portions 214 may be retracted into the side portion of structural body 201 until mating member 210 is at the second position.

In an embodiment, token lock 212 may secure (e.g., lock) mating member 210 into the first position or the second position until properly interacted with to revert the position of mating member 210 back to a prior position. For additional information regarding the token lock (e.g., during retraction of extended portions 214), refer to FIGS. 2C-2D.

It will be appreciated that although illustrated and described with respect to a first orientation of security bezel 200, security bezel 200 may be reversible (e.g., flipped) to a second orientation, as discussed with regard to FIGS. 1B-2A.

While illustrated in FIG. 2B with a limited number of specific components, a security bezel may include additional, fewer, and/or different components without departing from embodiments disclosed herein.

As noted above, mating member 210 may be manipulated by an interchangeable locking mechanism. For example, guiding arms 216 may be implemented with receptacles adapted to interact with portions of token lock 212, thereby allowing for manipulation of the receptacles by token lock 212. FIGS. 2C-2D show diagrams illustrating an example of the manipulation of mating member 210.

Turning to FIG. 2C, a third diagram illustrating a security bezel (e.g., 200) in accordance with an embodiment is shown. In FIG. 2C, the viewpoint may be the magnification of locking latch 208, as shown in FIG. 2B, however without a cover portion of token lock 212 (a top surface of the cover portion facing out of the page in FIGS. 2A-2B).

As previously discussed, receptacles of mating member 210 may be adapted to interact with an interchangeable locking mechanism, thereby allowing for manipulation of the receptacles by the interchangeable locking mechanism. In an embodiment, the interchangeable locking mechanism may be implemented by token lock 212, discussed below.

Token lock 212 may include the cover portion (not explicitly shown in FIG. 2C in order to illustrate internal mechanisms of token lock 212) and lock base 222. The cover portion and lock base 222 may attach to one another to securely encase the internal mechanisms of token lock 212.

For example, and as previously discussed, the lock space included in security bezel 200 may be adapted to receive (e.g., allow integration of) token lock 212 (e.g., a type of the interchangeable locking mechanism). The use of token lock 212 may be decided by, for example, an intended user of a data processing system of which security bezel 200 is to provide management of access for (management of access to the hardware components of the data processing system). Therefore, once chosen, calibrated, etc., the internal mechanisms of token lock 212 may be securely encased by attaching the cover portion to lock base 222.

By doing so, the internal mechanisms may be protected from exterior interference from, for example, an individual without explicit permissions to access the hardware components. Thus, a likelihood of compromise (e.g., caused by the individual) of token lock 212 (and thus, the hardware components) may be decreased.

To manage the access to the hardware components, the internal mechanisms of token lock 212 may be integrated with security bezel 200. To integrate the internal mechanisms, token lock 212 may include, for example, integration member 224.

Integration member 224 may facilitate the interaction with token lock 212 by the receptacles of mating member 210. To do so, integration member 224 may be adapted to, for example, receive the receptables. For example, integration member 224 may have a similar shape to that of extended portions 214 (e.g., the hook shape). When integrating token lock 212 into the lock space, integration member 224 may be coupled to the receptacles by causing hook shapes of integration member 224 to move into a default position (with respect to the receptacles) that is maintained due to the shape of the receptacles. Therefore, integration member 224 may be unable to decouple from the receptacles unless the internal mechanisms of token lock 212 are accessible (which the secure encasement prevents).

To further manage the access to the hardware components, integration member 224 may be manipulated, thereby causing a chain reaction of manipulation that results in repositioning of mating member 210.

To facilitate the chain reaction of manipulation, the internal mechanisms of token lock 212 may further include guiding base 226 and an interactive mechanism (e.g., a keypad, keyhole, scanner, etc.). Guiding base 226 may restrict movement of integration member 224 to a linear path between two positions, thereby contributing to a linear traversal of mating member 210. The interactive mechanism may directly cause the manipulation of integration member 224, for example, if interacted with in a particular manner.

For example, the position of mating member 210 in FIG. 2C may be the first position, previously discussed with regard to FIGS. 1B-2B. While in this first position, mating member 210 may extend away from token lock 212 (and out of the side portion of the chassis) by a distance. If the interactive mechanism is interacted with in the particular manner, retraction of mating member 210 may be initiated.

For additional information regarding the linear traversal, refer to FIG. 2D below.

Turning to FIG. 2D, a fourth diagram illustrating a security bezel (e.g., 200) in accordance with an embodiment is shown. In FIG. 2D, the viewpoint may be that of FIG. 2C.

As shown in FIG. 2D, mating member 210 may be retracted into the side portion of the chassis (depicted using white arrows). By retracting mating member 210, mating member 210 may be moved from the first position (as shown in FIG. 2C) to a second position (as shown in FIG. 2D).

As mentioned above, for example, if the interactive mechanism is interacted with in the particular manner, retraction of mating member 210 may be initiated. The retraction may be initiated by manipulating integration member 224, thereby causing the previously discussed chain reaction of manipulation.

It will be appreciated that although interaction with token lock 212 may cause repositioning of mating member 210 from a first to a second position, in an embodiment, the interaction with token lock 212 may instead cause repositioning of mating member 210 from the second position to the first position.

While illustrated in FIGS. 2C-2D with a limited number of specific components, a security bezel may include additional, fewer, and/or different components without departing from embodiments disclosed herein.

Turning to FIG. 2E, a fifth diagram illustrating a security bezel (e.g., 200) in accordance with an embodiment is shown. In FIG. 2E, the viewpoint may be from a perspective view of a security bezel (e.g., as shown in FIG. 1B). Additionally, token lock 212 is illustrated as not yet being integrated with security bezel 200 to illustrate security bezel 200 prior to the integration.

As previously mentioned, token lock 212 (e.g., an interchangeable locking mechanism) may be chosen by an intended user. Therefore, security bezel 200 may include a mating member and a lock space (e.g., 228) without, for example, token lock 212. Thus, the intended user may customize security bezel 200 to include an interchangeable locking mechanism chosen by the intended user.

Additionally, as previously discussed, guiding arms of the mating member may include receptacles (e.g., 230) adapted to interact with the chosen interchangeable locking mechanism. For example, integration member 224, discussed with regard to FIGS. 2C-2D, may have a hook shape that is adapted to interact with receptacles 230, resulting in a coupling between receptacles 230 and integration member 224.

While illustrated in FIGS. 2C-2D with a limited number of specific components, a security bezel may include additional, fewer, and/or different components without departing from embodiments disclosed herein.

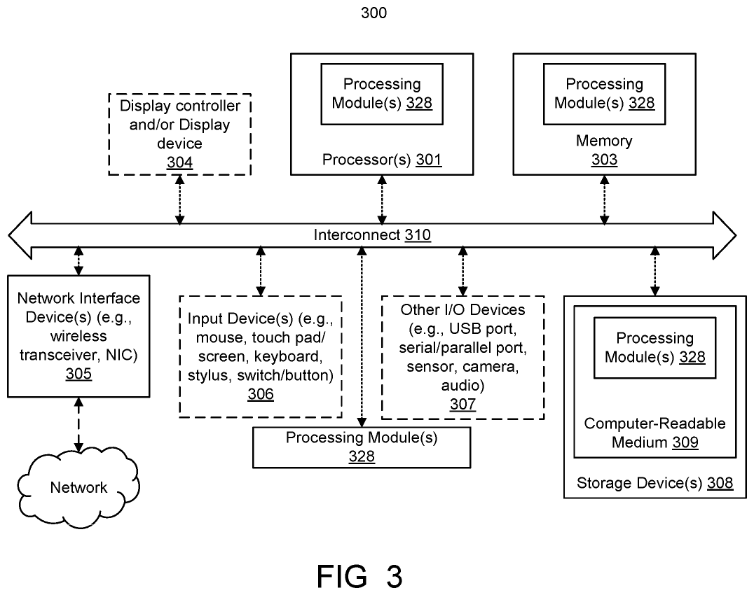

Any of the components illustrated in FIGS. 1A-2E may be implemented with and/or used in conjunction with one or more computing devices. For example, the security bezel may be used to secure a chassis in which components of a data processing system may be positioned (e.g., processors, memory, etc.). Turning to FIG. 3, a block diagram illustrating an example of a data processing system (e.g., a computing device) in accordance with an embodiment is shown. For example, system 300 may represent any of data processing systems described above performing any of the processes or methods described above. System 300 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 300 is intended to show a high-level view of many components of the computer system. However, it is to be understood that additional components may be present in certain implementations and furthermore, different arrangement of the components shown may occur in other implementations. System 300 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 300 includes processor 301, memory 303, and devices 305-307 via a bus or an interconnect 310. Processor 301 may represent a single processor or multiple processors with a single processor core or multiple processor cores included therein. Processor 301 may represent one or more general-purpose processors such as a microprocessor, a central processing unit (CPU), or the like. More particularly, processor 301 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 301 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 301, which may be a low power multi-core processor socket such as an ultra-low voltage processor, may act as a main processing unit and central hub for communication with the various components of the system. Such processor can be implemented as a system on chip (SoC). Processor 301 is configured to execute instructions for performing the operations discussed herein. System 300 may further include a graphics interface that communicates with optional graphics subsystem 304, which may include a display controller, a graphics processor, and/or a display device.

Processor 301 may communicate with memory 303, which in one embodiment can be implemented via multiple memory devices to provide for a given amount of system memory. Memory 303 may include one or more volatile storage (or memory) devices such as random-access memory (RAM), dynamic RAM (DRAM), synchronous DRAM (SDRAM), static RAM (SRAM), or other types of storage devices. Memory 303 may store information including sequences of instructions that are executed by processor 301, or any other device. For example, executable code and/or data of a variety of operating systems, device drivers, firmware (e.g., input output basic system or BIOS), and/or applications can be loaded in memory 303 and executed by processor 301. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 300 may further include IO devices such as devices (e.g., 305, 306, 307, 308) including network interface device(s) 305, optional input device(s) 306, and other optional IO device(s) 307. Network interface device(s) 305 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 306 may include a mouse, a touch pad, a touch sensitive screen (which may be integrated with a display device of optional graphics subsystem 304), a pointer device such as a stylus, and/or a keyboard (e.g., physical keyboard or a virtual keyboard displayed as part of a touch sensitive screen). For example, input device(s) 306 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 307 may include an audio device. An audio device may include a speaker and/or a microphone to facilitate voice-enabled functions, such as voice recognition, voice replication, digital recording, and/or telephony functions. Other IO devices 307 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 307 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 310 via a sensor hub (not shown), while other devices such as a keyboard or thermal sensor may be controlled by an embedded controller (not shown), dependent upon the specific configuration or design of system 300.

To provide for persistent storage of information such as data, applications, one or more operating systems and so forth, a mass storage (not shown) may also couple to processor 301. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 301, e.g., via a serial peripheral interface (SPI). This flash device may provide for non-volatile storage of system software, including a basic input/output software (BIOS) as well as other firmware of the system.

Storage device 308 may include computer-readable storage medium 309 (also known as a machine-readable storage medium or a computer-readable medium) on which is stored one or more sets of instructions or software (e.g., processing module, unit, and/or processing module/unit/logic 328) embodying any one or more of the methodologies or functions described herein. Processing module/unit/logic 328 may represent any of the components described above. Processing module/unit/logic 328 may also reside, completely or at least partially, within memory 303 and/or within processor 301 during execution thereof by system 300, memory 303 and processor 301 also constituting machine-accessible storage media. Processing module/unit/logic 328 may further be transmitted or received over a network via network interface device(s) 305.

Computer-readable storage medium 309 may also be used to store some software functionalities described above persistently. While computer-readable storage medium 309 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 328, components and other features described herein can be implemented as discrete hardware components or integrated in the functionality of hardware components such as ASICS, FPGAs, DSPs or similar devices. In addition, processing module/unit/logic 328 can be implemented as firmware or functional circuitry within hardware devices. Further, processing module/unit/logic 328 can be implemented in any combination hardware devices and software components.

Note that while system 300 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A security bezel for a chassis of a data processing system, the security bezel comprising:
a structural body for securing access to an interior of the chassis, the structural body forming a partial covering for a two-dimensional surface, the structural body adapted to:
facilitate traversal of gases through the two-dimensional surface, and
resist deformation due to force applied to the security bezel to maintain the partial covering for the two-dimensional surface, and
a locking latch adapted to reversibly secure the structural body to the chassis; and
a lock space to receive an interchangeable locking mechanism.

2. The security bezel of claim 1, wherein the locking latch comprises a retractable mating member comprising:
receptacles for making a first connection between the interchangeable locking mechanism and the retractable mating member to allow the interchangeable locking mechanism to move the retractable mating member between two positions, and
extended portions for making a second connection between the chassis and the retractable mating member while the retractable mating member is in a first position of the two positions, the structural body being secured to the chassis while the second connection is in place.

3. The security bezel of claim 2, wherein the security bezel is reversible, and the lock space accommodating insertion of the interchangeable locking mechanism from both sides of the security bezel.

4. The security bezel of claim 3, wherein the extended portions have an asymmetric shape, the asymmetric shape fixedly securing the structural body to the chassis while the security bezel is in a first orientation, and not securing the structural body to the chassis while the security body is in a second orientation, where reversing the security bezel from the first orientation places the security bezel in the second orientation.

5. The security bezel of claim 2, wherein the locking latch comprises a return spring adapted to return the extended portions to the first position from a second position of the two positions while the interchangeable locking mechanism is not applying any force to the retractable mating member.

6. The security bezel of claim 2, wherein the retractable mating member further comprises:
a member body, and
a first guiding arm extending from the member body, the first guiding arm comprising a receptacle of the receptacles, and
wherein the extended portions extend from the member body.

7. The security bezel of claim 6, wherein the first guiding arm restricts a motion path of the extended portions while the extended portions move between the first position and the second position.

8. The security bezel of claim 7, wherein the first guiding arm and the extended portions are on different sides of the member body.

9. The security bezel of claim 8, wherein the retractable mating member further comprises a second guiding arm, the second guiding arm being on an opposite side of the lock space from the first guiding arm.

10. The security bezel of claim 1, further comprising the interchangeable locking mechanism, the interchangeable locking mechanism adapted to be inserted into the lock space and mechanically coupled to portions of the locking latch while inserted in the lock space.

11. The security bezel of claim 10, wherein while mechanically coupled to the portions of the locking latch, actuation of the interchangeable locking mechanism reversibly secures the security bezel to the chassis.

12. An enclosure comprising:
a chassis; and
a security bezel for a chassis of a data processing system, the security bezel comprising:
a structural body for securing access to an interior of the chassis, the structural body forming a partial covering for a two-dimensional surface, the structural body adapted to:
facilitate traversal of gases through the two-dimensional surface, and
resist deformation due to force applied to the security bezel to maintain the partial covering for the two-dimensional surface, and
a locking latch adapted to reversibly secure the structural body to the chassis; and
a lock space to receive an interchangeable locking mechanism.

13. The enclosure of claim 12, wherein the locking latch comprises a retractable mating member comprising:
receptacles for making a first connection between the interchangeable locking mechanism and the retractable mating member to allow the interchangeable locking mechanism to move the retractable mating member between two positions, and
extended portions for making a second connection between the chassis and the retractable mating member while the retractable mating member is in a first position of the two positions, the structural body being secured to the chassis while the second connection is in place.

14. The enclosure of claim 13, wherein the security bezel is reversible, and the lock space accommodating insertion of the interchangeable locking mechanism from both sides of the security bezel.

15. The enclosure of claim 14, wherein the extended portions have an asymmetric shape, the asymmetric shape fixedly securing the structural body to the chassis while the security bezel is in a first orientation, and not securing the structural body to the chassis while the security body is in a second orientation, where reversing the security bezel from the first orientation places the security bezel in the second orientation.

16. The enclosure of claim 13, wherein the locking latch comprises a return spring adapted to return the extended portions to the first position from a second position of the two positions while the interchangeable locking mechanism is not applying any force to the retractable mating member.

17. A data processing system comprising:
a chassis;
hardware components positioned in the chassis; and
a security bezel for a chassis of a data processing system, the security bezel comprising:
a structural body for securing access to an interior of the chassis, the structural body forming a partial covering for a two-dimensional surface, the structural body adapted to:
facilitate traversal of gases through the two-dimensional surface, and
resist deformation due to force applied to the security bezel to maintain the partial covering for the two-dimensional surface, and
a locking latch adapted to reversibly secure the structural body to the chassis; and
a lock space to receive an interchangeable locking mechanism.

18. The data processing system of claim 17, wherein the locking latch comprises a retractable mating member comprising:
receptacles for making a first connection between the interchangeable locking mechanism and the retractable mating member to allow the interchangeable locking mechanism to move the retractable mating member between two positions, and
extended portions for making a second connection between the chassis and the retractable mating member while the retractable mating member is in a first position of the two positions, the structural body being secured to the chassis while the second connection is in place.

19. The data processing system of claim 18, wherein the security bezel is reversible, and the lock space accommodating insertion of the interchangeable locking mechanism from both sides of the security bezel.

20. The data processing system of claim 19, wherein the extended portions have an asymmetric shape, the asymmetric shape fixedly securing the structural body to the chassis while the security bezel is in a first orientation, and not securing the structural body to the chassis while the security body is in a second orientation, where reversing the security bezel from the first orientation places the security bezel in the second orientation.
